(19) United States
(12) Patent Application Publication
(10) Pub. No.: US 2009/0242396 A1
(43) Pub. Date: Oct. 1, 2009

(54) ADJUSTABLE MAGNET PACK FOR SEMICONDUCTOR WAFER PROCESSING

(75) Inventors: Jozef Brcka, Loundonville, NY (US); Ron Nasman, Averill Park, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited, Tokyo (JP)

(21) Appl. No.: 12/059,156

(22) Filed: Mar. 31, 2008

(51) Int. Cl. C23C 14/00

(52) U.S. Cl. 204/298.16

(57) ABSTRACT

A magnetron system is provided for a PVD system in which a magnet pack is formed in two subassemblies, one relatively moveable with respect to the other and one or both moveable relative to a sputtering target. The magnet pack may include a plurality of magnet rings that are interconnected by an annular yoke behind the magnets to provide a magnetic circuit with a magnetic field over the surface of the target. The yoke may be split into plural annular parts. By moving one or more parts of the yoke, such as by changing alignment of the yoke parts, the magnetic circuit can be changed during operation of process or at least without breaking the chamber vacuum. This allows the field strength on the surface of the target to be changed to control the utilization of the target over the life of the target, or to switch between strong and weak fields to perform a sequential deposition-etch process on a substrate in the chamber.

This invention disclosure is related to physical vapor deposition (PVD) and ionized PVD (iPVD), particularly involving magnetron sputtering target sources. This invention is more particularly related to magnet packs used in the magnetron sputtering sources.

### BACKGROUND OF THE INVENTION

Physical vapor deposition (PVD) and ionized PVD (iPVD) have been utilized in semiconductor processing for metallization and interconnects. The prior art iPVD processes and apparatus were described in U.S. Pat. Nos. 6,287,435; 6,080,287; 6,132,564; and 6,197,165, commonly owned by the assignee of the present application. Sputtering targets are typically used as the source of coating material in iPVD. Magnetron systems are common components of a sputter deposition apparatus to confine plasmas over the sputtering surface of a target to enhance deposition rates and to shape the utilization profile of the target as erosion of the target progresses over the target lifetime. U.S. Pat. No. 6,458,252 is an example of a magnet pack designed to optimize utilization of a sputtering target in an iPVD system.

For coating submicron features on semiconductors, multiple mode processes such as sequential iPVD and etching processes have been found useful, as described in the commonly assigned U.S. Pat. No. 6,755,945. With such processes, the use of magnetron technology has been found to assist in the deposition part of the process, but has been found to adversely affect uniformity during etching, as explained in the commonly assigned U.S. Patent Application Publication No. 2004/0188239.

In the commonly assigned U.S. Patent Application Pub. No. 2005/0279624, Applicants have disclosed a solution that is useful in sequential deposition-etch processes and in situ processing utilizing a quasi etch/deposition operation that moves magnetron magnets during processing without opening the chamber to impact on the plasma uniformity.

The prior art PVD and/or ionized PVD apparatus described, for example, in U.S. Pat. Nos. 6,287,435; 6,080,287; 6,197,165 and 6,132,564 utilize magnetpacks with magnetic fields that do not have the feature of control of the magnetic field over the target lifetime. U.S. Patent Application Publication No. 2005/0279624 describes moving the magnetic field envelope to impact the plasma distribution in connection with etch uniformity control.

There remains a need to control target surface erosion without interrupting vacuum operation in a PVD or an ionized PVD tool. There is also a need to control the lifetime deposition rate and deposition uniformity. In the performance of sequential deposition-etch processes, there is a need to allow uninterruptible dual mode process operation as, for example, in “etch/deposition”, “preconditioning/deposition”, “cleaning/deposition” processes, and in other processes to change the magnetic field effects of magnetron systems between the sequential deposition and etching modes of the process.

### SUMMARY OF THE INVENTION

An objective of the present invention is to control target surface erosion without interrupting vacuum operation in a PVD or an ionized PVD tool. A further objective of the invention is to control lifetime deposition rate and deposition uniformity from a sputtering target in a PVD or iPVD system. A particular objective of the invention is to allow uninterruptible dual mode process operation as, for example, in “etch/deposition”, “preconditioning/deposition”, “cleaning/deposition” and other processes, without breaking chamber vacuum. Another objective of the invention is to facilitate dual mode sequential processing in which magnetic fields are differently maintained during the different modes of the process. A specific objective of the invention is to provide a magnetron system that can achieve the above objectives.

According to principles of the present invention, a magnet pack is provided behind a sputtering target in a sputtering chamber with at least two annular magnet rings interconnected by a yoke in a magnetic circuit that produces a magnetic field over a sputtering surface of the sputtering target. The magnetic circuit is changed by moving at least part of the yoke relative to at least one of the magnet rings. The change may be controlled by changing of the magnetic circuit over the life of the target to control the erosion profile and utilization of the target. Also, the change may be performed in connection with the performing of a sequential deposition and etching process by changing the magnetic circuit to produce a strong magnetic field over the sputtering surface of the target during a deposition portion of the process and to produce a relatively weak magnetic field over the sputtering surface of the target during an etch portion of the process.

According to certain embodiments of the invention, a physical vapor deposition apparatus is provided with a magnetron system having a magnet pack on the backside of a sputtering target, where the magnet pack includes an inner annular magnet ring and an outer annular magnet ring with an annular yoke magnetically interconnecting the magnet rings in a magnetic circuit. The magnet rings are between the yoke and the target and produce a static magnetic field over the sputtering surface of the sputtering target. The magnet pack is formed in at least two subassemblies, each including one or more of the magnet rings or one or more parts of the yoke. One or both of the subassemblies are moveable relative to the target so that the subassemblies are moveable relative to each other between two relative positions, including a strong-field position and a weak-field position, changing the magnetic circuit to change the static magnetic field at the sputtering surface of the target. An actuator is operably linked to the magnet pack to move the annular subassemblies one relative to the other between the strong-field position and the weak-field position.

In some embodiments, the yoke has at least two concentric annular parts between the inner and outer magnet rings dividing the magnet pack into the at least two annular subassemblies. The subassemblies are moveable relative to each other between the strong-field position in which the parts of the yoke are closely spaced and aligned and the weak-field position in which the parts of the yoke are less closely spaced or less aligned. One subassembly may be a static subassembly fixed to a sputtering target while the other or both subassemblies may be moveable relative to the sputtering target.

In some embodiments, one subassembly is a static subassembly fixed to a sputtering target and has one or more annular parts of the yoke fixed thereto, while the other subassembly is moveable relative to the sputtering target and has one or more annular parts of the yoke fixed thereto. Inner and outer magnet rings may, for example, may be fixed to parts of the yoke on the moveable subassembly. The subassemblies may be continuously moveable relative to each other between a strong-field position and a weak-field position through a plurality of intermediate positions in which the parts of the yoke become less closely spaced or less aligned in relation to their distance from the strong-field position.

In other embodiments, a plurality of annular magnet rings includes a central annular magnet ring positioned between an outer annular magnet ring and an inner annular magnet ring. A yoke is provided in three annular parts, including an inner annular part fixed to the inner ring, an outer annular part fixed to the outer ring, and a central annular part fixed to the central magnet ring. A first subassembly may include at least one of the inner or outer magnet rings and corresponding annular parts of the yoke and a second subassembly may include the central magnet ring and the central annular part of the yoke.

In certain embodiments, magnet rings may be provided that each includes a first annular pole and a second and opposite annular pole defining a polar axis, with an outer magnet ring having a polar axis oriented perpendicular to the yoke and inner and central magnet rings provided having polar axes oriented parallel to each other, in opposite directions and perpendicular to the polar axis of the outer magnet ring, with the inner magnet ring having its first pole facing the central magnet ring and the outer magnet ring having its first pole facing away from the yoke.

In various embodiments, a plasma processing system is provided with displacement of an individual subassembly of a magnet pack in a manner that changes the static magnetic field at the target surface. Target lifetime erosion control can thereby be provided by changing the actual magnetic circuit within the magnet pack. This gives independent control of the target lifetime by providing independent control of the magnetic field at the target surface over the target lifetime. It also allows for adjustment of the deposition rate over the target lifetime, and adjustment or corrections to the erosion shape of the target surface. Adjustment of the magnetic field at the target surface for different process applications is also provided within the same chamber without breaking vacuum. The invention provides inherent technical simplicity.

In various embodiments, the magnet pack has a moveable subassembly that moves symmetrically around its axis and that of the chamber so that its effects are symmetrical around the axis. In illustrated embodiments, this movement is parallel to the axis. In other embodiments, parts may move symmetrically in other ways, such as azimuthally, or radially.

These and other objects and advantages of the present invention will be more readily apparent from the following detailed description of illustrated embodiments of the invention.

### BRIEF DESCRIPTION OF THE DRAWINGS

FIG. 1 is a diagrammatic cross-sectional representation of an ionized physical vapor deposition (iPVD) apparatus of the prior art for which the present invention is useful.

FIG. 1A is a an enlarged cross-sectional view of the circled portion 1A of FIG. 1.

FIG. 2 is a simplified cross-sectional diagram of a magnet pack embodying principles of the present invention.

FIG. 2A is another diagram of the magnet pack of FIG. 2 with portions thereof adjusted to a different relative position.

FIGS. 3A-3F are diagrams illustrating the magnet pack of FIGS. 2 and 2A in which portions thereof are shown in a series of different relative positions.

FIG. 4 is a cross-sectional diagram of a magnet pack similar to that of FIG. 1A but further embodying principles of the present invention.

FIGS. 4A-4B are cross-sectional diagrams of the magnet pack of FIG. 4 showing portions thereof in different relative positions.

### DETAILED DESCRIPTION OF THE ILLUSTRATED EMBODIMENTS OF THE INVENTION

Sputter deposition is a form of physical vapor deposition (PVD) that is commonly used for depositing a film onto semiconductor wafer substrates. In sputter deposition, a sputtering target supplies coating material that is vaporized in a vacuum chamber by bombarding the target surface with ions of gas from a plasma. Magnetron magnets are typically employed behind, or otherwise adjacent, the sputtering target to confine the plasma near the target surface, thereby increasing the sputtering rate and controlling the plasma distribution over the target surface so that the target is consumed more uniformly.

Ionized PVD (iPVD) is an advanced form of PVD that is being used more recently to deposit film, particularly metals, onto wafers on which submicron sized features make up the semiconductor devices being manufactured. Such processes include the metallization of high aspect ratio via and trench structures on silicon wafers such as those that form barrier and seed layers. In iPVD, sputtered material is ionized in a high density plasma, often formed by an inductively coupled plasma (ICP) so that the material can be better directed onto the nano-features on the wafer's surface. Targets for iPVD are usually equipped with magnetron magnets.

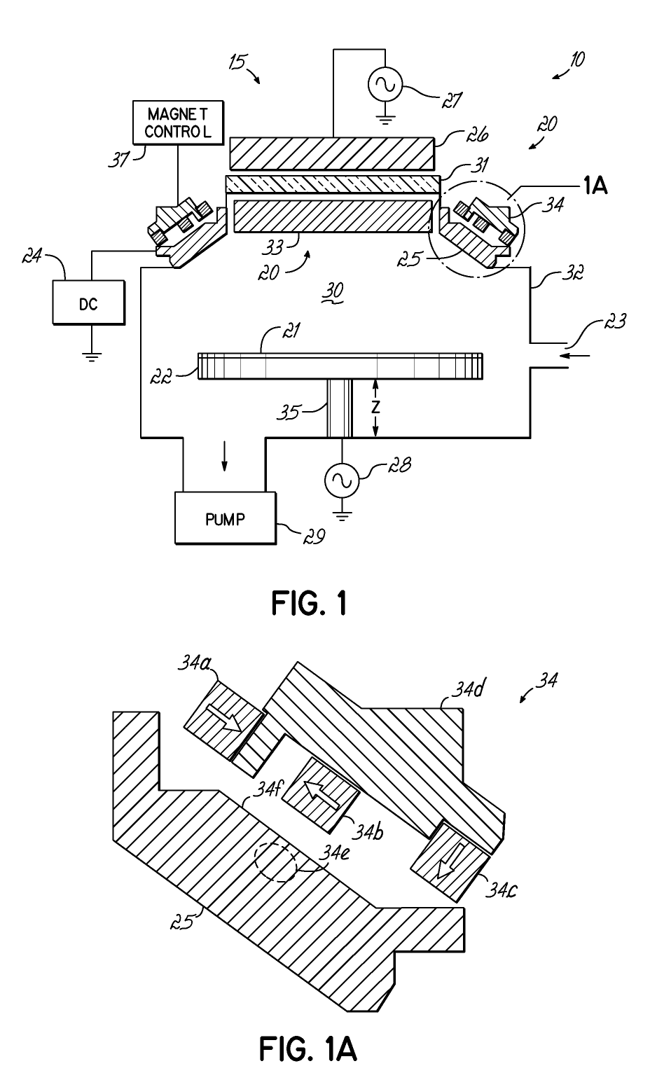

An iPVD apparatus 10 in which the present invention can be embodied is illustrated in FIG. 1. This apparatus is described in more detail in U.S. Pat. Nos. 6,287,435 and 6,719,886, hereby expressly incorporated by reference herein. For iPVD performed in the apparatus 10, a wafer 21 is held in a vacuum chamber 30 on a wafer table or substrate support 22, which may be, for example, a temperature-controlled electrostatic chuck. The wafer table 22 may also be equipped with a Z-motion drive 35 to adjust the substrate-to-source distance to optimize deposition uniformity and the coverage and symmetry of the sidewalls and bottoms of the vias and other features on the substrate.

Sputtering gas is supplied from a gas source 23 into a vacuum processing chamber 30 enclosed by a chamber wall 32. Pressure in the chamber 30 is maintained at a vacuum pressure level by a pump 29 that is set or adjusted to a proper ionized deposition range for iPVD. DC power is supplied from a power source 24 to an ionized material source 20 that includes a sputtering target 25 and an ICP source 15. The ICP source 15 includes an antenna 26 to which RF power is supplied from an RF generator 27. These electrical power sources 24 and 27 are operated at power levels appropriate for deposition by iPVD. The RF power 27 energizes a high-density inductively-coupled plasma in a process volume in the chamber 30 between the target 25 and the wafer 21.

Wafer RF bias is supplied to the chuck 22 by an RF bias generator 28, which can also be set at a level appropriate during deposition to provide a net negative bias on the wafer 21 that controls the flux of ions onto the wafer 21 to affect and improve the deposition process. The antenna 26 is often positioned outside of the chamber 30 behind a dielectric window 31 in the chamber wall 32. A louvered deposition baffle 33, preferably formed of a slotted metallic material, is located inside of the chamber 30 closely spaced from the window 31 to shield the window 31 from deposition while facilitating the coupling of a magnetic field from the antenna 26 and the plasma in the chamber 30.

For the magnetron of the apparatus 10, a magnet pack 34 is located behind the target 25 to produce a magnetic tunnel over the target 25 for magnetron sputtering. The magnet pack 34 is typically a permanent magnet assembly that is designed to confine a plasma over the target surface and to shape the plasma so that the target erodes in a way that maximizes its utilization. Details of the magnet pack 34 are described in U.S. Pat. No. 6,458,252, hereby expressly incorporated by reference herein. The fixed components of the magnet pack 34 are configured and arranged to control the sputtering plasma shape over the life of the target.

As illustrated in FIGS. 1 and 1A, the magnet pack 34 may be an annular magnet pack that can be made up of three annular rows of magnets 34a, 34b and 34c, each of rectangular cross section, magnetically interconnected with an annular yoke 34d. The magnets 34a, 34b and 34c and yoke 34d can each be configured in a circle, oriented to generate magnetic fields parallel to the target surface, and having a null-B point 35e, at the centerline of the annular target 25 close to the target-to-backplane boundary 34f, where the B-fields from the magnets cancel.

The basic structure of the apparatus 10 can be used for sequential deposition and etching, which is a process particularly useful for coating the bottoms and sidewalls of high aspect ratio, submicron trenches and vias. These processes are explained in detail in U.S. Patent Application Publication No. 2004/0188239 and U.S. Pat. No. 6,755,945, hereby expressly incorporated by reference herein. Application No. 2004/0188239 includes a description of adverse effects of static magnetic fields from the magnetron magnets on the etch portions of the dep-etch cycle in these processes, along with ways for minimizing such adverse effects. U.S. Patent Application Publication No. 2005/0279624, also expressly incorporated by reference herein, describes structure by which magnetron magnets may be moved to minimize their adverse effects on the etch portions of dep-etch processes and to compensate for factors that might cause non-uniformities on a wafer. This structure includes a magnet control 37, which is also diagrammatically illustrated in FIG. 1. This magnet control 37 can adjust the magnets to change the magnet field strength between deposition and etch modes.

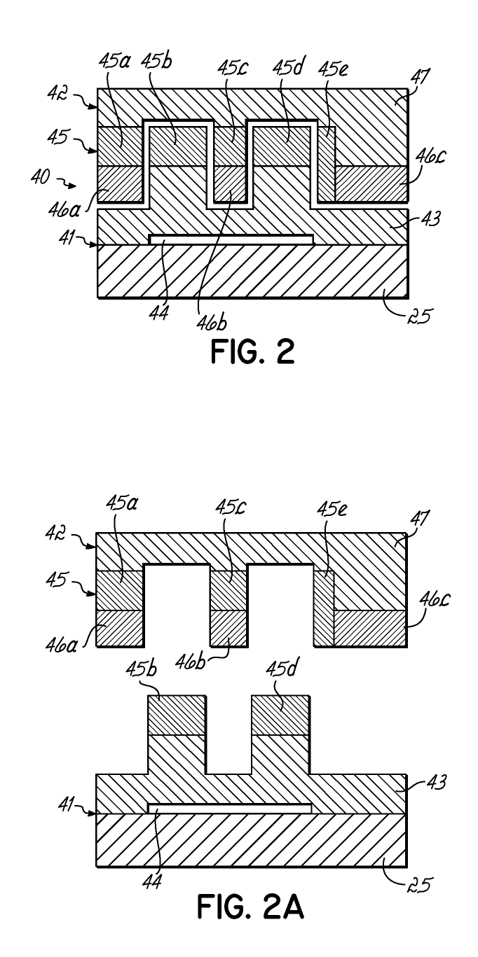

According to principles of the present invention, a magnetron system is provided in which a magnet pack, for example the magnet pack 34 of FIGS. 1 and 1A, is provided with the features of a magnet pack 40, an embodiment of which is illustrated diagrammatically in FIG. 2. The magnet pack 40 includes two assemblies, magnet pack assembly 41 and magnet pack assembly 42. The magnet pack assembly 41 may be a static magnet assembly, which is connected to the target 25 and includes a backing plate 43, which is connected to the target 25 and encloses a cooling space 44 for liquid cooling between the backing plate 43. The yoke 34 of FIG. 1A is provided in the form of a split yoke 45 having five annular portions 45a-45e. Two portions 45b and 45d of the yoke 45 are attached to the backing plate 43.

The other magnet pack assembly 42 is a moveable assembly that can be repositioned, for example, by moving it vertically or otherwise, such as parallel to an axis of the PVD or IPVD source 20. The magnet pack assemblies 41 and 42 may be generally symmetrical around an axis of the source 20 and consist of magnet sets arranged in a particular configuration. Yoke portions 45a, 45c and 45e of the yoke 45 are fixed to a unifying non-magnetic plate 47. The magnet pack 40 is provided with magnets 46a, 46b and 46c that may be in the form of the annular ring magnets 34a, 34b and 34c of the magnet pack 34 shown in FIG. 1A. The magnets 46a, 46b and 46c are respectively mounted on the yoke portions 45a, 45c and 45e, as illustrated in FIG. 2. When the moveable assembly 42 is in a lowered or otherwise closed position, as illustrated in FIG. 2, the yoke portions 45a-45e form a generally aligned yoke assembly 45. In this closed position, which will be referred to as the Strong B-field Position or SBP, both magnet pack assemblies 41 and 42 are arranged together congruently such that a strong magnetic field will be produced at the surface of the target 25.

The moveable magnet assembly 42 is moveable to a raised or otherwise open position as illustrated in FIG. 2A. In this open position, which will be referred to as the Weak B-field Position or WBP, the moveable magnet assembly 42 is distanced from static magnet assembly 41 in a direction parallel to the axis of the source assembly 20. In this WBP position, magnetic flux is weakened due to air bridges formed between the magnet assemblies 41 and 42 in which the portions 45a, 45c, and 45e of the yoke 45 are out of alignment with, and spaced from, the other yoke portions 45b and 45d. The arrangement illustrated in FIGS. 2 and 2A is applicable to planar or conical annular targets, planar disk-shaped targets, and to other target configurations. For simplicity a planar annular target 25 with a planar magnet pack 40 is shown. In addition, movement of the magnets 45a-45c from the target 25 also influences the magnetic field at the target 25. However, the movement of the magnets 45 and the separation of the yoke portions 45a-45e may be employed either separately or together to achieve the purposes of the invention.

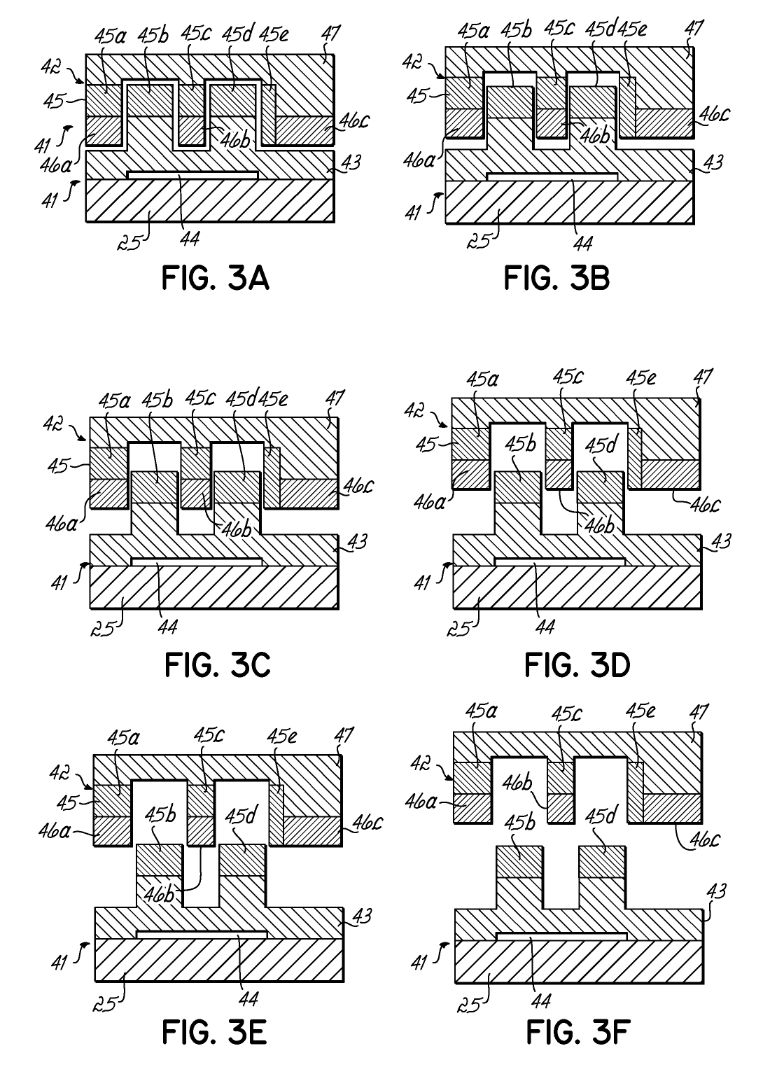

To compensate for erosion of the target 25, the magnet assembly 42 is moved a distance, which may be only a small distance, to reduce the magnetic field at the eroded target surface, but not so far as to change an original purpose and function of the magnet pack of confining a sputtering plasma close to the sputtering surface of the target. As shown in FIGS. 3A-3F, the motion between two magnet assemblies 41 and 42 can be continuous so that the distance between the magnet assemblies 41 and 42 is continuously adjustable. In this way, the magnetic field can be adjusted in small steps to compensate for magnetic field changes due to erosion of the target, to correct and control the erosion of the target over the target lifetime, or to adjust, or compensate for changes in, various process conditions.

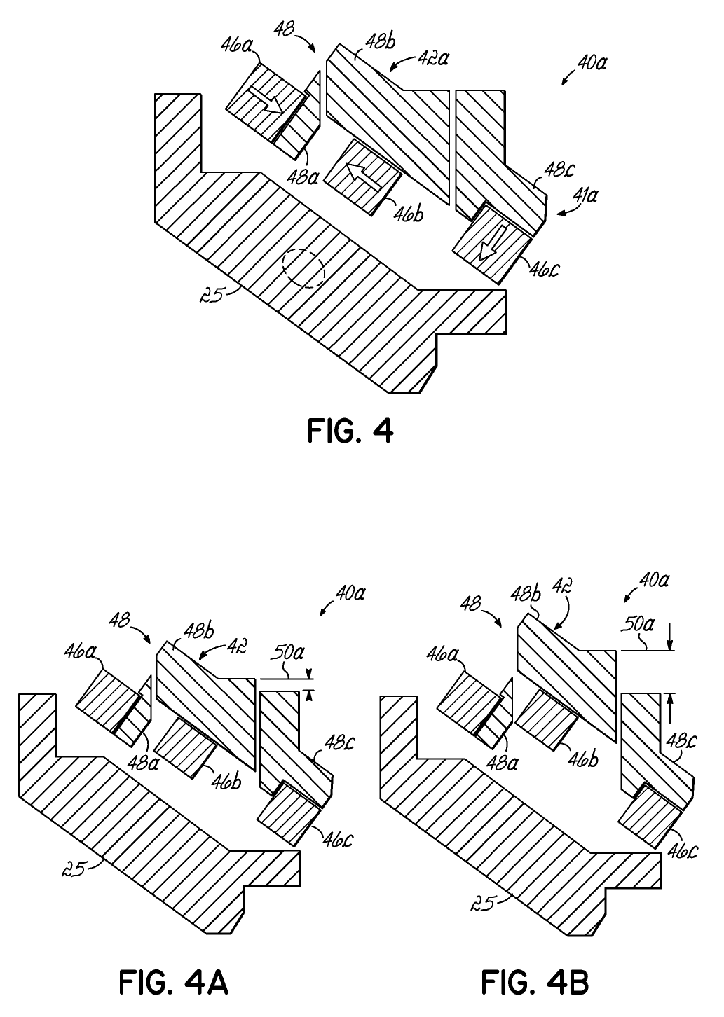

FIG. 4 illustrates another embodiment 40a of the magnet pack 40 in which a magnet pack in the configuration of the magnet pack 34 of FIG. 1A is configured into two magnet assemblies 41a and 42a. The magnet pack 40a is shown in cross-section that is configured for high utilization of an annular conical target 25 of the type shown in FIG. 1A. In the magnet pack 40a, the yoke 34d of FIG. 1A is divided into three parts in the form of a split yoke 48 having portions 48a, 48b and 48c, each having a respective one of the magnets 46a, 46b and 46c mounted thereon. The yoke portions 48a and 48c along with magnets 46a and 46c are part of the static magnet assembly 41, which is fixed relative to the target 25, while the yoke portion 48b and magnet 46b are part of the moveable magnet assembly 42 that is moveable relative the static assembly 41 and the target 25. When the moveable assembly 42 is in the closed position, as illustrated in FIG. 4, the yoke portions 48a-48c form a generally aligned yoke assembly 48. This closed position is the Strong B-field Position or SBP, in which both magnet pack assemblies 41 and 42 are arranged together congruently such that a strong magnetic field will be produced at the surface of the target 25.

FIGS. 4A and 4B illustrate the magnet pack 40a in which the moveable magnet assembly 42 is moved respectively to an intermediate, partially open, position (FIG. 4A) and a more fully open position (FIG. 4B) in which the moveable magnet assembly 42 is moved to progressively open positions. In the open position of FIG. 4B, the Weak B-field Position or WBP is achieved in which the moveable magnet assembly 42 is distanced from the static magnet assembly 41 so that the magnetic flux is weakened because the portions 48a and 48c of the yoke 48 are out of alignment with, and spaced from, the other yoke portions 48b. The arrangement illustrated in FIGS. 2 and 2A is applicable to planar or conical annular targets.

Further, movement of the central magnet ring 34b from the target 25 changes the magnetic field shape at the target 25. The movement of the magnet 34b and the separation of the yoke portions 48a-48c may be employed either separately or together to achieve the purposes of the invention. Displacement 50 of the central yoke portion 48b with respect to the magnet pack assembly 42 can be made to provide small scale adjustments 50a (FIG. 4A) to the magnet pack through a displacement in the order of several millimeters (mm) as well as larger scale adjustments 50b (FIG. 4B) through displacement of the magnet pack assembly 42 in the order of 10 mm or more.

The magnetron system according to the present invention is particularly suitable for implementation in ionized physical vapor deposition, such as in the iPVD tool, for example, as described in U.S. Pat. Nos. 6,080,287, 6,287,435, 6,197,165 and 6,458,252. In these tools, the sputtering of the annular conical target has been enhanced and erosion profile controlled by an annular magnet pack consisting of three rows of the rectangular magnets and a yoke configured and oriented, as illustrated in FIGS. 1 and 1A, in a way to generate a magnetic field parallel to the target surface and having null-B point 55 at the centerline of the annular body close to the target-to-backplane boundary. The cross section of such a target assembly 25 is shown in FIG. 4, modified according to the present invention to extend lifetime performance of the target 25 under multi-mode operation, for example, in the dual-mode in-situ sequential deposition/etch process.

In iPVD in the apparatus 10 of FIG. 1, the metal vapor flux from the target 25 may be thermalized at an argon pressure that is higher than typical sputtering pressures (>30 mTorr). The axially positioned ICP source 15 produces high density plasma and effective ionization of the metal in a central area of the processing chamber 30 and between the source 15 and the wafer 21. Metal ions diffuse towards the wafer surface and, in dependence on bias power applied to the substrate, the ions are more or less accelerated across a plasma sheath by a potential difference between the plasma potential and the potential at the wafer surface.

During a typical ionized PVD process, it is expected that increased magnet field strength of the permanent magnet arrangement 34 near the target 25 increases electron confinement, thereby increasing localized ions and the sputtering rate. When a high density plasma is available from the ICP source 15, the requirement for the trapped electrons around the cathode to generate gas ions is reduced due to the high plasma density from the ICP. Therefore, achievement of a reasonable sputtering rate of material from the target 25 is less dependent on the local strength of the magnetic field from the magnet pack 34. However, the magnetic field still has an impact on the erosion profile evolution of the target 25. Consequently, a desirable cathode erosion pattern makes it preferable to continue use of a local magnetic field, even when the ICP produces substantial ions for sputtering the target 25.

The etch portion of a sequential deposition/etch process requires conditions that are different than those for the deposition portion of the process. The etch conditions usually include reduced pressure below 10 mTorr, and elimination of target sputtering, or at least reduction or elimination of the interaction of the magnetron magnetic field generated by the magnet pack 34 of the target 25 with a plasma. The interaction of the magnetic field from the magnetron reduces the etch uniformity and introduces variable feature coverage across the wafer surface.

With the features of the magnet pack 40, displacement of the magnet pack subassembly 42 can be provided by suitable actuators, most useful for sequential processing, to move the two magnet assemblies 41 and 42 between closed and open positions as illustrated in FIGS. 2 and 2A. This can be achieved using pneumatic or electric activation, for example, as represented by the magnet control 37 in FIG. 1. In addition, small progressive adjustments can be made for target lifetime erosion compensation and control, adjusting the magnetic field incrementally, as illustrated in FIGS. 3A-3F. The adjustment can be made by a maintenance procedure without breaking chamber vacuum. The detailed application of such actuators is well known to system engineers working in the field. Examples are disclosed in the commonly assigned patents and applications referred to above and incorporated into this application, such as U.S. Patent Application Publication No. 2005/0279624, and in U.S. Pat. No. 6,464,841, hereby expressly incorporated by reference herein.

Those skilled in the art will appreciate that deletions, additions and modifications can be made to the above described embodiments without departing from the principles of the invention. Therefore, the following is claimed:

1. A magnetron system for a semiconductor wafer PVD processing apparatus comprising:
a magnet pack comprising a plurality of concentric annular magnet rings, including an inner annular magnet ring and an outer annular magnet ring, having a common central axis, and an annular yoke magnetically interconnecting the magnet rings;
the yoke having at least two concentric annular parts between the inner and outer magnet rings dividing the magnet pack into at least two annular subassemblies, moveable relative to each other symmetrically around the common central axis between two positions, including a strong-field position in which the parts of the yoke are closely spaced and aligned and a weak-field position in which the parts of the yoke are less closely spaced or less aligned; and
an actuator operably linked to the magnet pack to move the annular subassemblies one relative to the other between the strong-field position and the weak-field position.

2. The system of claim 1 wherein:
one subassembly is a static subassembly fixed to a sputtering target; and
the other subassembly is a moveable subassembly moveable axially relative to the sputtering target.

3. The system of claim 1 wherein:
one subassembly is a static subassembly fixed to a sputtering target and has one or more annular parts of the yoke fixed thereto;
the other subassembly is a moveable subassembly moveable axially relative to the sputtering target and has one or more annular parts of the yoke fixed thereto; and
the inner and outer magnet rings are fixed to parts of the yoke on the moveable subassembly.

4. The system of claim 1 wherein:
one subassembly is a static subassembly fixed to a sputtering target; and
the other subassembly is a moveable subassembly that includes parts moveable at least partially azimuthally relative to the sputtering target.

5. The system of claim 1 wherein:
one subassembly is a static subassembly fixed to a sputtering target and has one or more annular parts of the yoke fixed thereto;
the other subassembly is a moveable subassembly that includes parts moveable at least partially azimuthally relative to the sputtering target and has one or more annular parts of the yoke fixed thereto; and
the inner and outer magnet rings are fixed to parts of the yoke on the moveable subassembly.

6. The system of claim 1 wherein:
the subassemblies are continuously moveable relative to each other between the strong-field position and the weak-field position through a plurality of intermediate positions in which the parts of the yoke become less closely spaced or less aligned in relation to their distance from the strong-field position; and
the actuator is operable to move the subassemblies progressively through the positions.

7. The system of claim 1 wherein:
the plurality of annular magnet rings includes a central annular magnet ring positioned between the outer annular magnet ring and the inner annular magnet ring;
the yoke is divided into three annular parts, including an inner annular part having the inner ring fixed thereto, an outer annular part having the outer ring fixed thereto, and a central annular part having the central magnet ring fixed thereto; and
the at least two subassemblies include a first subassembly comprising at least one of the inner or outer magnet rings and corresponding annular parts of the yoke and a second subassembly comprising the central magnet ring and the central annular part of the yoke.

8. The system of claim 1 wherein:
the plurality of annular magnet rings includes a central annular magnet ring positioned between the outer annular magnet ring and the inner annular magnet ring;
the yoke is divided into three annular parts, including an inner annular part having the inner ring fixed thereto, an outer annular part having the outer ring fixed thereto, and a central annular part having the central magnet ring fixed thereto; and
the at least two subassemblies include a static subassembly fixed relative to a sputtering target and comprising the inner or outer magnet rings and corresponding annular parts of the yoke and a moveable subassembly comprising the central magnet ring and the central annular part of the yoke.

9. The system of claim 8 wherein:
the magnet rings each include a first annular pole and a second and opposite annular pole defining a polar axis;
the outer magnet ring has a polar axis oriented perpendicular to the yoke;
the inner and central magnet rings have polar axes oriented parallel to each other, in opposite directions and perpendicular to the polar axis of the outer magnet ring; and
the inner magnet ring having its first pole facing the central magnet ring and the outer magnet ring having its first pole facing away from the yoke.

10. A physical vapor deposition apparatus comprising:
a vacuum chamber having a sputtering target at one end thereof and a substrate support at the other end thereof, the target having a sputtering surface facing the substrate support and a backside facing away from the substrate support; and
the magnetron system of claim 1 wherein the magnet pack is situated on the backside of the sputtering target with the magnet rings thereof between the yoke and the target and producing a magnetic field extending over the sputtering surface of the sputtering target.

11. The apparatus of claim 10 further comprising:
a controller having an output communicating with the actuator and programmed to activate the actuator to move the annular subassemblies one relative to the other between the strong-field position and the weak-field position in accordance with the erosion of the target.

12. The apparatus of claim 10 wherein:
the subassemblies are continuously moveable relative to each other between the strong-field position and the weak-field position through a plurality of intermediate positions in which the parts of the yoke become less closely spaced or less aligned in relation to their distance from the strong-field position;
the actuator is operable to move the subassemblies progressively through the positions; and
the apparatus further comprises a controller having an output communicating with the actuator and programmed to activate the actuator to move the annular subassemblies one relative to the other progressively through the positions between the strong-field position and the weak-field position in accordance with the erosion of the target.

13. The apparatus of claim 10 further comprising:
a controller programmed to operate the apparatus sequentially in a deposition mode, then an etch mode, then a deposition mode, then an etch mode; and
the controller being further programmed to activate the actuator to move the annular subassemblies one relative to the other to the strong-field position during the deposition modes and the weak-field position during the etch modes.

14. A physical vapor deposition apparatus comprising:
a vacuum chamber having a sputtering target at one end thereof and a substrate support at the other end thereof, the target having a sputtering surface facing the substrate support and a backside facing away from the substrate support;
the magnetron system having a magnet pack situated on the backside of the sputtering target;
a magnet pack comprising a plurality of concentric annular magnet rings, including an inner annular magnet ring and an outer annular magnet ring and an annular yoke having one or more annular parts magnetically interconnecting the magnet rings in a magnetic circuit, the magnet rings being between the yoke and the target and producing a static magnetic field extending over the sputtering surface of the sputtering target;
the magnet pack including at least two annular subassemblies, each including one or more of the magnet rings or one or more parts of the yoke, the subassemblies being moveable relative to each other between two positions, including a strong-field position and a weak-field position, by changing the magnetic circuit to change the static magnetic field at the sputtering surface of the target; and
an actuator operably linked to the magnet pack to move the annular subassemblies one relative to the other between the strong-field position and the weak-field position.

15. The apparatus of claim 14 wherein:
the yoke has at least two concentric annular parts between the inner and outer magnet rings dividing the magnet pack into the at least two annular subassemblies; and
the subassemblies are moveable relative to each other between the strong-field position in which the parts of the yoke are closely spaced and aligned and the weak-field position in which the parts of the yoke are less closely spaced or less aligned.

16. The apparatus of claim 14 wherein:
the yoke has at least two concentric annular parts between the inner and outer magnet rings dividing the magnet pack into the at least two annular subassemblies;
the subassemblies are continuously moveable relative to each other between the strong-field position and the weak-field position through a plurality of intermediate positions in which the parts of the yoke become less closely spaced or less aligned in relation to their distance from the strong-field position;
the actuator is operable to move the subassemblies progressively through the positions; and
the apparatus further comprises a controller having an output communicating with the actuator and programmed to activate the actuator to move the annular subassemblies one relative to the other progressively through the positions between the strong-field position and the weak-field position in accordance with the erosion of the target.

17. The apparatus of claim 14 further comprising:
a controller having an output communicating with the actuator and programmed to activate the actuator to move the annular subassemblies one relative to the other between the strong-field position and the weak-field position in accordance with the erosion of the target.

18. The apparatus of claim 14 further comprising:
a controller programmed to operate the apparatus sequentially in a deposition mode, then an etch mode, then a deposition mode, then an etch mode; and
the controller being further programmed to activate the actuator to move the annular subassemblies one relative to the other to the strong-field position during the deposition modes and the weak-field position during the etch modes.

19. The apparatus of claim 14 wherein:
one subassembly is a static subassembly fixed to a sputtering target; and
the other subassembly is a moveable subassembly moveable relative to the sputtering target.

20. The apparatus of claim 14 wherein:
one subassembly is a static subassembly fixed to a sputtering target and has one or more annular parts of the yoke fixed thereto;
the other subassembly is a moveable subassembly moveable axially relative to the sputtering target and has one or more annular parts of the yoke fixed thereto; and
the inner and outer magnet rings are fixed to parts of the yoke on the moveable subassembly.

21. The apparatus of claim 14 wherein:
the subassemblies are continuously moveable relative to each other between the strong-field position and the weak-field position through a plurality of intermediate positions in which the parts of the yoke become less closely spaced or less aligned in relation to their distance from the strong-field position; and
an actuator is operable to move the subassemblies progressively through the positions.

22. The apparatus of claim 14 wherein:
the plurality of annular magnet rings includes a central annular magnet ring positioned between the outer annular magnet ring and the inner annular magnet ring;
the yoke is divided into three annular parts, including an inner annular part having the inner ring fixed thereto, an outer annular part having the outer ring fixed thereto, and a central annular part having the central magnet ring fixed thereto; and
the at least two subassemblies include a first subassembly comprising at least one of the inner or outer magnet rings and corresponding annular parts of the yoke and a second subassembly comprising the central magnet ring and the central annular part of the yoke.

23. The apparatus of claim 14 wherein:
the plurality of annular magnet rings includes a central annular magnet ring positioned between the outer annular magnet ring and the inner annular magnet ring;
the yoke is divided into three annular parts, including an inner annular part having the inner ring fixed thereto, an outer annular part having the outer ring fixed thereto, and a central annular part having the central magnet ring fixed thereto; and
the at least two subassemblies include a static subassembly fixed relative to a sputtering target and comprising the inner or outer magnet rings and corresponding annular parts of the yoke and a moveable subassembly comprising the central magnet ring and the central annular part of the yoke.

24. The apparatus of claim 23 wherein:
the magnet rings each include a first annular pole and a second and opposite annular pole defining a polar axis;
the outer magnet ring has a polar axis oriented perpendicular to the yoke;
the inner and central magnet rings have polar axes oriented parallel to each other, in opposite directions and perpendicular to the polar axis of the outer magnet ring; and
the inner magnet ring having its first pole facing the central magnet ring and the outer magnet ring having its first pole facing away from the yoke.

25. A physical deposition method comprising:
providing a magnet pack behind a sputtering target in a sputtering chamber with at least two annular magnet rings interconnected by a yoke in a magnetic circuit that produces a magnetic field over a sputtering surface of the sputtering target; and
changing the magnetic circuit by moving at least part of the yoke relative to at least one of the magnet rings.

26. The method of claim 25 further comprising:
controlling the changing of the magnetic circuit over the life of the target to control the erosion of the target.

27. The method of claim 25 further comprising:
performing a sequential deposition and etching process on a substrate in a processing chamber having the sputtering target therein; and
controlling the changing of the magnetic circuit to produce a strong magnetic field over the sputtering surface of the target during a deposition portion of the sequential deposition and etch process and to produce a relative weak magnetic field over the sputtering surface of the target during an etch portion of the sequential deposition and etch process.
